(19) United States
(12) Patent Application Publication
(10) Pub. No.: US 2024/0213321 A1
(43) Pub. Date: Jun. 27, 2024

(54) Tunneling Enabled Feedback FET

(71) Applicant: IMEC VZW, Leuven (BE)

(72) Inventor: Aryan Afzalian, Chastre (BE)

(21) Appl. No.: 18/545,730

(22) Filed: Dec. 19, 2023

(30) Foreign Application Priority Data
Dec. 22, 2022 (EP) 22216117.6

(51) Int. Cl. H01L 29/08; H01L 29/06; H01L 29/10; H01L 29/16; H01L 29/43

(52) U.S. Cl. CPC H01L 29/0895; H01L 29/0665; H01L 29/1033; H01L 29/1606; H01L 29/432

(57) ABSTRACT

Example embodiments relate to tunneling enabled feedback field effect transistors (FETs). One example system includes a feedback field effect transistor. The feedback field effect transistor includes a source region. The feedback field effect transistor also includes a channel region. Additionally, the feedback field effect transistor includes a drain region. Further, the feedback field effect transistor includes a gate. The channel region is between the source region and the drain region. The source region, the channel region, and the drain region include a semiconductor material with a bandgap that is smaller than 0.9 eV. The source region or the drain region has a dopant concentration that is smaller than 5×10¹⁹ cm⁻³. The gate is positioned along the channel and isolated from the channel.

### CROSS-REFERENCE TO RELATED APPLICATIONS

The present application is a non-provisional patent application claiming priority to Patent Application No. EP 22216117.6, filed Dec. 22, 2022, the contents of which are hereby incorporated by reference.

### FIELD OF THE DISCLOSURE

The disclosure relates to the field of field effect transistors (FETs). More specifically it relates to a feedback field effect transistor.

### BACKGROUND

With an increasing number of semiconductor devices per chip a decreasing device size is needed. Typical device dimensions today range from a few nm to tens of nm, making the pursuit of dimension scaling increasingly difficult. As a consequence, semiconductor devices are evolving from planar metal-oxide-semiconductor (MOS) structures to 3D multigated transistors such as FinFETs or nanowires (NW) and novel material like 2D materials or carbon nanotubes (CNTs) are sought after. Among other issues, power consumption and heat dissipation have become a key concern in modern complementary metal-oxide-semiconductor (CMOS) technologies due to the ever-increasing number of transistors per unit area, and improved energy efficient switches are sought as replacement to the MOSFET concept.

In a MOSFET, the lower limit for the subthreshold slope (SS), or the inverse slope of the drain current—gate voltage characteristic ID(V_{G}) of a transistor, is ln(10)×kT/q. In other words, at least 60 mV of gate voltage variation may be used to change the current by a decade at room temperature. This sets a practical limit to reductions of supply voltage and power consumption of a circuit. Achieving steeper-subthreshold-slope transistors has become a key concern for further CMOS downscaling, and different concepts to overcome this limitation have been proposed. This includes devices using a multi-physic effect triggered by V_{G}, such as electromechanical motion in the Suspended-Gate (SG)-MOSFET or replacing the standard gate insulator with a ferroelectric insulator of the right thickness in the ferroelectric FET. Other concepts attempt to use impact ionization, or energy filtering with tunnel barriers and resonant tunneling in the Resonant Tunneling FET (RTFET), using a superlattice to create minibands in the Superlattice FET, or by using band-to-band tunneling (BTBT) through gate modulation of a reverse-biased positive-negative (PN) junction in a tunnel FET (TFET), or using a so called cold-source metal in the cold-source FET. Despite the progress in the field, a satisfying steep-slope device is still missing and VDD has not been scaled below 0.7 V.

It has also been shown that a positive feedback mechanism can lead to a steep subthreshold slope (SS) in the Feedback field effect transistors (FBFETs). FBFETs are devices based on a positive feedback loop in which the electrons and holes in the channel region act on the energy states of the potential barrier and wall. FBFETs were first proposed in 2008. The design of the FBFET is similar, with a positive-intrinsic-negative (P-I-N) diode under forward bias. It exhibits positive feedback with double potential barriers. Surrounding the channel region close to the source and drain, gate-sidewall spacers fabricated to trap charges play the role of potential barriers on the FBFET. Each barrier that blocks the flow of electrons and holes makes it possible to utilize P-I-N diodes as FBFETs. Typically, these devices use more complex structures than a regular MOSFET, such as PNPN structures or P-I-N structure with at least 2 gates and rely on 2 reservoirs (typically where electrons and holes are exchanged) that are spatially separated (close to the source and drain, gate-sidewall spacers). This renders the fabrication process more complex and may make it more difficult to scale down such devices.

There is therefore a need for alternative designs for FBFETs which may be better suited to scale down the FBFETs.

### SUMMARY

Embodiments of the present disclosure provide a straightforward design of a FBFET and a method for making such a FBFET.

The above is accomplished by a method and device according to the present disclosure.

In a first aspect, embodiments of the present disclosure relate to a FBFET. The FBFET comprises a source region, a channel region, a drain region, and a gate.

The source region, the channel region, and the drain region comprise a semiconductor material with a bandgap which is smaller than 0.9 eV and the source region, the drain region, or both have a dopant concentration that is smaller than 5×10¹⁹ cm⁻³.

The gate is positioned along the channel and isolated from the channel.

In some embodiments of the present disclosure the semiconductor material is a carbon nanotube. In some embodiments of the present disclosure the semiconductor material is germanium, III-V material, graphene, or black phosphorus.

In some embodiments of the present disclosure the drain region has a dopant concentration that is smaller than 5×10¹⁹ cm⁻³ and the source region has a dopant concentration of more than 5×10¹⁹ cm⁻³.

In some embodiments of the present disclosure a dopant of the source is an n-type dopant. In some embodiments of the present disclosure a dopant of the source is a p-type dopant.

In some embodiments of the present disclosure the device comprises a source electrode in contact with the source region, and a drain electrode in contact with the drain region.

In some embodiments of the present disclosure a length of the channel is between 3 nm and 100 nm.

In some embodiments of the present disclosure a length of the source or drain is between 3 nm and 40 nm.

Some embodiments of the present disclosure may also relate to a logic device comprising a plurality of FBFETs according to embodiments of the present disclosure, wherein the FBFETs are arranged in a logic configuration.

Some embodiments of the present disclosure may also relate to a memory device comprising a FBFET according to embodiments of the present disclosure. The memory device is configured for determining whether the feedback field effect transistor is in a high or low conductive state based on a conductivity of the feedback field effect transistor.

In a second aspect embodiments of the present disclosure relate to a method for operating a FBFET. The method comprises applying a drain-source voltage between the drain region and the source region. The drain-source voltage may be at least 0.2 V.

The method, furthermore, comprises increasing the gate voltage from 0 V to a first predefined gate voltage until a drain polarity reverts, and increasing the gate voltage from the first predefined gate voltage to a second predefined gate voltage to switch on the feedback field effect transistor.

Some embodiments are set out in the accompanying independent and dependent claims. Features from the dependent claims may be combined with features of the independent claims and with features of other dependent claims as appropriate and not merely as explicitly set out in the claims.

These and other aspects of the disclosure will be apparent from and elucidated with reference to the embodiment(s) described hereinafter.

### BRIEF DESCRIPTION OF THE FIGURES

FIG. 1 shows a 3D schematic drawing of an example FBFET, in accordance with embodiments of the present disclosure.

FIG. 2 shows the drain current as a function of the gate voltage of a FBFET, in accordance with embodiments of the present disclosure.

FIG. 3 shows the subthreshold slope as a function of the drain current for a FBFET, in accordance with embodiments of the present disclosure.

FIG. 4 shows the conduction band profile along the channel direction (x) for various gate voltages V_{G} in a first phase of the forward sweep of a FBFET, in accordance with embodiments of the present disclosure.

FIG. 5 shows the conduction band profile along the channel direction (x) for various gate voltages V_{G} in a second phase of the forward sweep of a FBFET, in accordance with embodiments of the present disclosure.

FIG. 6 shows the conduction band profile along the channel direction (x) for various gate voltages V_{G} in a third phase of the forward sweep of a FBFET, in accordance with embodiments of the present disclosure.

FIG. 7 shows the channel bands along the channel direction in a fourth phase of the forward sweep of a FBFET, in accordance with embodiments of the present disclosure.

FIG. 8 shows the carrier concentration along the channel direction in a first phase and in a third phase of a FBFET, in accordance with embodiments of the present disclosure.

FIG. 9 shows the carrier concentration along the channel direction for various gate voltages of a FBFET, in accordance with embodiments of the present disclosure.

FIG. 10 shows the band profile and the current spectrum J(E) along the channel direction for various gate voltages of a FBFET, in accordance with embodiments of the present disclosure.

FIG. 11 shows the drain current as a function of the gate voltage of a FBFET, in accordance with embodiments of the present disclosure.

Any reference signs in the claims shall not be construed as limiting the scope.

In the different drawings, the same reference signs refer to the same or analogous elements.

### DETAILED DESCRIPTION

The present disclosure will be described with respect to some embodiments and with reference to certain drawings but the disclosure is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice.

The terms first, second, and the like in the description and in the claims, are used for distinguishing between similar elements and not necessarily for describing a sequence, either temporally, spatially, in ranking, or in any other manner. It is to be understood that the terms so used are interchangeable under appropriate circumstances and that the embodiments described herein are capable of operation in other sequences than described or illustrated herein.

It is to be noticed that the term “comprising”, used in the claims, should not be interpreted as being restricted to the elements listed thereafter; it does not exclude other elements or steps. It is thus to be interpreted as specifying the presence of the stated features, integers, steps, or components as referred to, but does not preclude the presence or addition of one or more other features, integers, steps, or components, or groups thereof. Thus, the scope of the expression “a device comprising A and B” should not be limited to devices consisting only of components A and B. It means that with respect to the present embodiment, the only relevant components of the device are A and B.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of example embodiments, various features are sometimes grouped together in a single embodiment, figure, or description thereof for the purpose of streamlining the disclosure and aiding in the understanding of one or more of the various disclosed aspects. This method of disclosure, however, is not to be interpreted as reflecting an intention that the claimed subject matter requires more features than are expressly recited in each claim. Rather, as the following claims reflect, disclosed aspects lie in less than all features of a single foregoing disclosed embodiment. Thus, the claims following the detailed description are hereby expressly incorporated into this detailed description, with each claim standing on its own as a separate embodiment.

Furthermore, while some embodiments described herein include some but not other features included in other embodiments, combinations of features of different embodiments are meant to be within the scope of the disclosure, and form different embodiments, as would be understood by those in the art. For example, in the following claims, any of the claimed embodiments can be used in any combination.

In the description provided herein, numerous specific details are set forth. However, it is understood that embodiments of the disclosure may be practiced without these specific details. In other instances, well-known methods, structures, and techniques have not been shown in detail in order not to obscure an understanding of this description.

This disclosure proposes a type of band-to-band-tunneling (BTBT) enabled FBFET that can work with a single gate and does not require a P-I-N structure. It may include a low bandgap material such as CNT, Ge, or a III-V material (e.g. InAs, InSb, etc.). Other low bandgap 2D materials such as graphene, black Phosphorus, etc. can also be used.

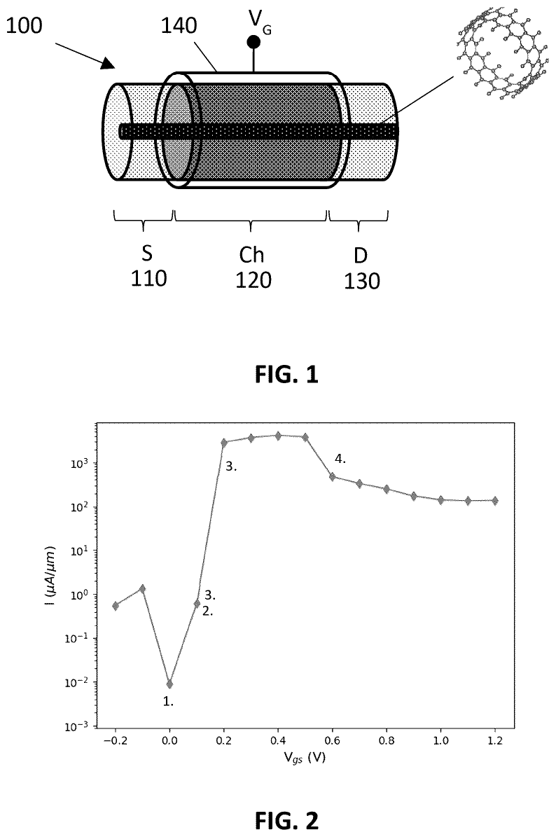

In a first aspect, embodiments of the present disclosure relate to a feedback field effect transistor (FBFET) 100. A 3D schematic drawing of an example embodiment of such FBFET is shown in FIG. 1. In some embodiments of the present disclosure the FBFET comprises a source region 110, a channel region 120, a drain region 130, and a gate 140.

The channel region 120 is between the source region 110 and the drain region 130. The source region 110, the channel region 120, and the drain region 130 are comprising a semiconductor material with a bandgap that is smaller than 0.9 eV. The bandgap may, for example, be between 0.7 and 0.5 eV.

The source region 110 and/or the drain region 130 may have a dopant concentration that is smaller than 5×10¹⁹ cm⁻³ and the gate is positioned along the channel and isolated from the channel. The gate may be a single gate (SG), double gate (DG), triple gate, gate all around (GAA). In the example in FIG. 1, the gate is a cylindrical gate (GAA) with tₒₓ=3 nm and εₒₓ=23.4.

Some embodiments of the present disclosure may benefit because the exchange of n and p can be triggered by band to band tunneling from the conduction band to the valence band within a single (non-spatially separated) channel region. This is possible because the semiconductor material of the field effect transistor has a bandgap that is smaller than 0.9 eV and because the source region and/or the drain region may have a dopant concentration that is smaller than 5×10¹⁹ cm⁻³. In some embodiments of the present disclosure any dopant suitable for effectively doping the material or even electrostatic doping may be used.

In some embodiments of the present disclosure the dopant concentration of the drain may, for example, be smaller than 2×10¹⁹ cm⁻³ or even smaller than or equal to 1×10¹⁹ cm⁻³.

In some embodiments of the present disclosure the dopant concentration of the source may be more than 1×10¹⁹ cm⁻³, or even equal to or more than 2×10¹⁹ cm⁻³, or even equal to or more than 5×10¹⁹ cm⁻³. In some embodiments of the present disclosure the drain region 130 has a dopant concentration that is smaller than 5×10¹⁹ cm⁻³ and the source region 110 has a dopant concentration of more than 5×10¹⁹ cm⁻³.

Some embodiments of the present disclosure may provide for abrupt switching by changing the charge carrier type from electron (n) to hole (p) abruptly within a region or reservoir (e.g., the channel barrier) when turning a n-type device from off to on (and vice versa for a p-type device). This may provide an abrupt collapse of the energy barrier of the region and a very steep transition from an off state to an on state.

Thus, some embodiments of the present disclosure may provide for field effect transistors with a steep subthreshold slope.

In some embodiments of the present disclosure the source, the drain, and the channel can be made of the same semiconductor material with bandgap smaller than 0.9 eV. In some embodiments of the present disclosure heterojunction materials may be used such that the effective bandgap is smaller than 0.9 eV, e.g. to ensure proper band to band tunneling between the source and the channel.

In some embodiments of the present disclosure a dopant of the source 110 is an n-type dopant. In such embodiments the dopant of the drain may be n-type, intrinsic, or may even be p-type. The doping of the drain is sufficiently low so that the band (position in energy with regards to the Fermi-level) is not fully degenerated/fixed by the doping.

In some embodiments of the present disclosure a dopant of the source 110 is a p-type dopant. In such embodiments the dopant of the drain may be p-type, intrinsic, or may even be n-type. The doping of the drain is sufficiently low so that the band (position in energy with regards to the Fermi-level) is not fully degenerated/fixed by the doping.

The operation principle of a FBFET in accordance with embodiments of the present disclosure is explained using an n-type transistor. The p-type operation is also understood based on the n-type mechanism.

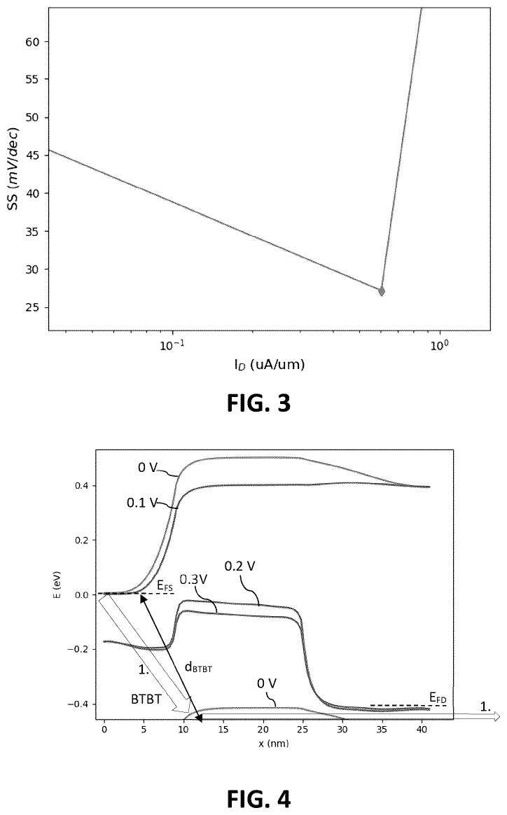

For explaining the operation principle an n-type CNT tunneling-enhanced FBFET in accordance with embodiments of the present disclosure is used. Such an FBFET is illustrated in FIG. 1. In this example the CNT has a diameter of 1.1 nm. For this example the drain 130 is doped with a donor concentration of 10¹⁹ cm⁻³. FIG. 2 shows the drain current ID versus gate voltage V_{G} characteristics in a forward sweep of a CNT tunneling enhanced FBFET, in accordance with embodiments of the present disclosure. The channel length for this example was 16 nm. A steep slope of 25 mV/decade is obtained. This is illustrated in FIG. 3 which shows the subthreshold slope as a function of the drain current. In this example the drain voltage is 0.4 V.

When the device is switched to the off-state and the gate voltage V_{G} is such that due to band bending the valence channel energy barrier at the source side lies in proximity of the source conduction band, an electronic band-to-band-tunneling (BTBT) current is flowing from the source conduction band to the transistor valence band in the channel and to the drain. Proximity thereby means that the band is sufficiently close to enable a strong BTBT current, this can happen even before the bands are aligned in energy via high-energy (optical) phonon-assisted tunneling.

In a low bandgap material, such as if the drain band is lightly doped (e.g., lightly n-type doped, intrinsic, or even lightly p-type) such that the band is not fully degenerated/fixed by the doping (the drain Fermi level lies in the bandgap), the polarity of the band can be inverted or made more strongly p-type due to the holes flowing in the drain due to the BTBT current if this current is strong enough. The Fermi level at the drain-side is then pinned towards the valence band due to the BTBT current and the structure behaves like an n-type intrinsic p-type (NIP) device, although by doping the device may have been designed n-type intrinsic n-type (NIN). In other words, the valence band at the drain-side is moved toward higher energies (phase 1). This allows any hole trapped in the channel valence band potential band barrier to escape to the drain-side (FIG. 4). As a consequence, an abrupt decrease of the positive charge (holes) in the channel triggers an abrupt increase of the channel energy barriers and an abrupt switching off the device. Due to this feedback mechanism, a small V_{G} change can induce a very abrupt and steep slope switching.

FIGS. 2 to 10 illustrate a forward sweep in more detail.

FIG. 2 shows the drain current versus gate voltage V_{G} characteristics in a forward sweep.

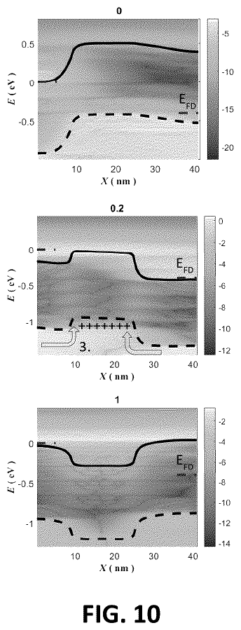

FIG. 4 shows the conduction band profile along the channel direction (x) for various gate voltages V_{G}. In a first phase of a forward sweep of a FBFET in accordance with embodiments of the present disclosure, the gate voltage V_{G} is 0 V. For V_{G}=0 V, the top of the valence band is also visible. The BTBT distance at the source side between the valence band and the conduction band is indicated by dBTBT. In the first phase (phase 1.) dBTBT is sufficiently low such that the BTBT current and the transport charges it carries are high enough to invert the drain polarity. For V_{G}<0.2 V (phase 1.), the drain Fermi level E_{FD} is pinned towards the valence band due to BTBT current flowing from the source side (see also the top graph of FIG. 10).

FIG. 10 shows the band profile and the current spectrum J(E) along the channel direction for V_{G}=0 V (top graph), for V_{G}=0.2 V (middle graph), and for V_{G}=1 V (bottom graph).

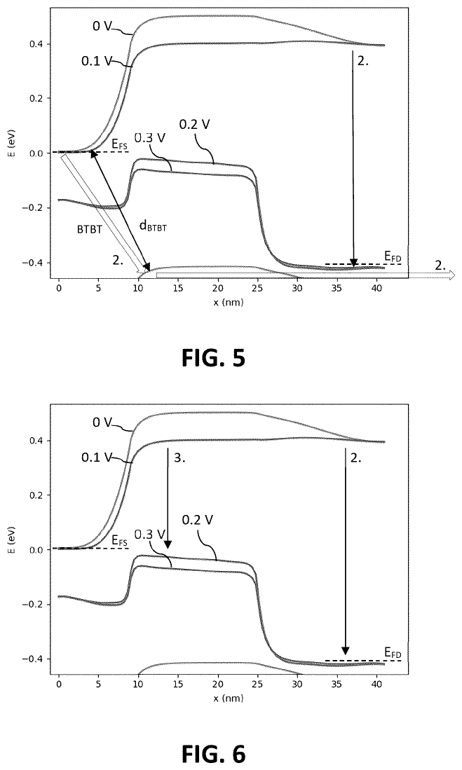

FIG. 5 shows the conduction band profile along the channel direction (x) for various gate voltages V_{G}. In FIG. 5 the second phase of the forward sweep of a tunneling FBFET in accordance with an example embodiment of the present disclosure is further illustrated. As V_{G} is increased the BTBT tunneling distance dBTBT is increasing and the BTBT current is reduced until the drain polarity reverts. For V_{G} approaching 0.2V (phase 2.) the energy bands at drain side are shifting down in energy. In particular, the conduction band shift towards the drain Fermi level E_{FD} (see also middle graph of FIG. 10). Phase 2 is a metastable/transient phase that will not last as it will immediately trigger phase 3. As the conduction band is shifting towards the drain Fermi level E_{FD}, this will allow for holes to fill the channel and trigger the feedback mechanism of phase 3.

FIG. 6 shows the conduction band profile along the channel direction (x) for various gate voltages V_{G}. In FIG. 6, as well as in the middle graph of FIG. 10 that shows both Ec and Ev profile at V_{G}=0.2 V, the third phase of the forward sweep of a tunneling FBFET in accordance with an example embodiment of the present disclosure is further illustrated. For V_{G} substantially equal to 0.2 V, immediately after the drain Fermi level E_{FD} has shifted towards the conduction band, the holes get trapped in the channel valence quantum well (phase 3.) and the channel barrier collapses. This is the feedback mechanism that enables a rapid drive current increase and the abrupt steep slope switching of the third phase (see FIG. 2 phase 3.).

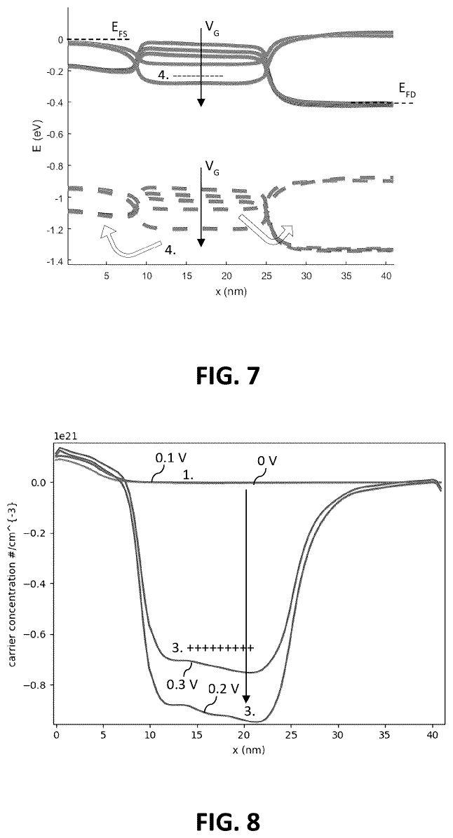

In FIG. 7 is illustrated that as V_{G} is further increased, the channel bands are pushed towards lower energy, and holes get de-trapped, while electron concentration is increased (see also bottom graph of FIG. 10) (phase 4.). This tends to counterbalance the electrostatic push of the gate potential so that after abrupt switch on, the current increases slowly, can even drop for increasing V_{G} and tends to saturate (see also FIG. 2 phase 4.).

FIG. 8 shows the carrier concentration (n-p) along the channel direction (x). For V_{G}<0.2 V (phase 1.) there are no trapped holes in the channel as the holes can escape from the channel via the drain. For V_{G} substantially equal to 0.2 V the holes get trapped (phase 3.) in the channel valence quantum well.

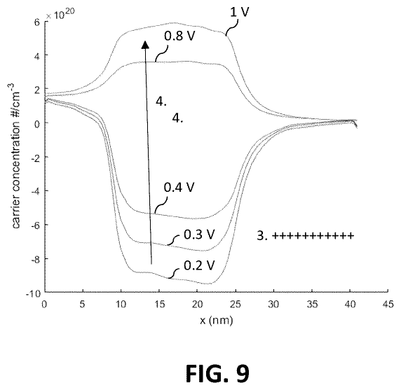

FIG. 9 shows the carrier concentration (n-p) along the channel direction (x). In the third phase the holes are trapped in the channel valence quantum well. In the fourth phase holes are de-trapped and electron concentration is increasing which is indicated with the upward arrow in FIG. 9.

In some embodiments of the present disclosure extensions or metal contacts may be provided at the drain without compromising the operation of the device. Even with these extensions or metal contact it is still possible to reverse the polarity at the drain side. In some embodiments of the present disclosure the device may for example comprise a source electrode in contact with the source region, and a drain electrode in contact with the drain region. Some embodiments of the present disclosure may benefit because the polarity at the drain side can still be reversed when a source and drain contact is present. The polarity at the drain-side cannot be reverted and the steep SS is lost if both source and drain sides are highly doped (>5×10¹⁹ cm⁻³).

In some embodiments of the present disclosure the length of the channel, and the length of the gate may, for example, be between 3 nm and 100 nm. The length of the source or drain may, for example, range between 3 nm and 40 nm.

Some embodiments of the present disclosure also relate to a logic device. Such a logic device comprises a plurality of feedback field effect transistors according to any of the previous descriptions, wherein the feedback field effect transistors are arranged in a logic configuration. The logic device may for example be an inverter comprising two feedback field effect transistors of opposite polarity which are arranged such that an inverter is obtained. Some embodiments of the present disclosure may benefit by enabling low-power logic with steep subthreshold slope operation (e.g. sub 60 mV/decade SS operation).

In a second aspect, embodiments of the present disclosure relate to a method for operating a feedback field effect transistor. The method comprises applying a drain-source voltage between the drain region and the source region wherein the drain-source voltage is at least 0.2 V. The drain-source voltage may for example be between 0.2 and 0.55 V, for example between 0.35 and 0.4 V.

The method, furthermore, comprises increasing the gate voltage from 0 V to a first predefined gate voltage until the drain polarity reverts, and increasing the gate voltage from the first predefined voltage to a second predefined voltage to switch on the feedback field effect transistor.

Some embodiments of the present disclosure may benefit because, by applying a drain-source voltage between the drain region and the source region wherein the drain-source voltage is at least 0.2 V, a band to band tunneling occurs and results in an inversion of the drain polarity. By increasing the gate voltage to the first predefined voltage the band to band tunneling current decreases and results in a reverting drain polarity. At this point the charge carriers get trapped in the channel resulting in an abrupt barrier collapse. This feedback mechanism enables a rapid drive current increase and steep slope switching. The first predefined voltage for the gate may, for example, range between 0 V and 0.3 V, and the second predefined voltage for the gate may, for example, range between 0.2 V and 0.5 V and may be equal to the supply voltage VDD that is also applied between the source and drain (VDS) of the device in a digital circuit.

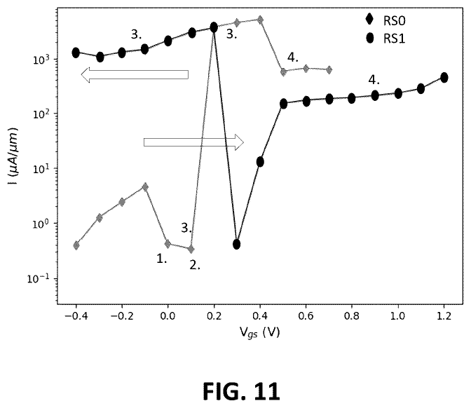

The graph shown in FIG. 2 illustrates the source drain current as a function of the gate source voltage obtained by executing a method implementing a forward sweep in accordance with some embodiments of the present disclosure. In some embodiments of the present disclosure a backward sweep may also be applied. In a backward sweep the same method steps are applied in the reverse order, i.e. from a higher V_{gs} to a lower V_{gs} for an n-type device. This is, for example, illustrated in FIG. 11. The arrow pointing to the right indicates the direction of the V_{gs} sweep for a forward sweep RS0, and the left indicates the direction of the V_{gs} sweep for a backward sweep RS1. It can be seen that there is hysteresis between a backward sweep followed be a forward sweep and a forward sweep followed by a backward sweep resulting in a difference in conductivity at a reference gate voltage (e.g. V_{gs}=0 V). This difference in conductivity can be used to obtain a memory device.

Some embodiments of the present disclosure also relate to a memory device. Such a memory device comprises a FBFET in accordance with some embodiments of the present disclosure. The memory device is configured for determining whether the FBFET is in a high or a low impedance state based on a conductivity of the FBFET.

This is possible because there is hysteresis between a forward and a backward sweep.

In some embodiments of the present disclosure the feedback field effect transistor acts as a memory element and can be either in a low or high conductive state at a given reference gate voltage V_{gth} (e.g., V_{gs}=0 V in FIG. 10) depending if the transistor underwent a full backward-forward cycle (low conductive state) or a forward-backward cycle (from V_{gth} to V_{gth}) owing to the hysteresis inherent to this device.

What is claimed is:

1. A system comprising:
a feedback field effect transistor comprising:
a source region;
a channel region;
a drain region; and
a gate,
wherein the channel region is between the source region and the drain region,
wherein the source region, the channel region, and the drain region comprise a semiconductor material with a bandgap that is smaller than 0.9 eV,
wherein the source region or the drain region has a dopant concentration that is smaller than 5×10¹⁹ cm⁻³, and
wherein the gate is positioned along the channel and isolated from the channel.

2. The system according to claim 1, wherein the semiconductor material is a carbon nanotube.

3. The system according to claim 1, wherein the semiconductor material is germanium, a III-V material, graphene, or black phosphorus.

4. The system according to claim 1, wherein the drain region has a dopant concentration that is smaller than 5×10¹⁹ cm⁻³, and wherein the source region has a dopant concentration of more than 5×10¹⁹ cm⁻³.

5. The system according to claim 1, wherein a dopant of the source region is an n-type dopant.

6. The system according to claim 1, wherein a dopant of the source region is a p-type dopant.

7. The system according to claim 1, wherein a dopant of the drain region has a same polarity as a dopant of the source region.

8. The system according to claim 1, further comprising:
a source electrode in contact with the source region; and
a drain electrode in contact with the drain region.

9. The system according to claim 1, wherein a length of the channel region is between 3 nm and 100 nm.

10. The system according to claim 1, wherein a length of the source region or the drain region is between 3 nm and 40 nm.

11. A logic device comprising a plurality of feedback field effect transistors according to claim 1, wherein the feedback field effect transistors are arranged in a logic configuration.

12. The logic device of claim 11, wherein the logic configuration operates with low-power logic.

13. The logic device of claim 12, wherein operating with low-power logic comprises operating with a subthreshold slope of less than 60 m V/decade.

14. A memory device comprising the feedback field effect transistor according to claim 1, wherein the memory device is configured for determining whether the feedback field effect transistor is in a high-conductive state or a low-conductive state based on a conductivity of the feedback field effect transistor.

15. A method for operating the system according to claim 1, the method comprising:
applying a drain-source voltage between the drain region and the source region, wherein the drain-source voltage is at least 0.2 V;
increasing a voltage of the gate from 0 V to a first predefined gate voltage until a drain polarity reverts; and
increasing the voltage of the gate from the first predefined gate voltage to a second predefined gate voltage to switch on the feedback field effect transistor.

16. The method of claim 15, wherein the drain-source voltage is between 0.2 V and 0.55 V.

17. The method of claim 15, where in the drain-source voltage is between 0.35 V and 0.4 V.

18. The method of claim 15, wherein the first predefined gate voltage is between 0 V and 0.3 V.

19. The method of claim 15, wherein the second predefined gate voltage is between 0.2 V and 0.5 V.

20. A method for operating the system according to claim 1, the method comprising:
applying a drain-source voltage between the drain region and the source region, wherein the drain-source voltage is at least 0.2 V; and
decreasing a voltage of the gate from a first predefined gate voltage to a second predefined gate voltage until a drain polarity reverts, wherein the second predefined gate voltage is lower than the first predefined gate voltage.
